(19) United States
(12) Patent Application Publication
(10) Pub. No.: US 2011/0135133 A1
(43) Pub. Date: Jun. 9, 2011

(54) LIQUID CRYSTAL DISPLAY DEVICE

(76) Inventors: Sang Joon Choi, Chilgok-gun (KR); Young Min Kweon, Gumi-si (KR); Sang Ryeon Park, Gumi-si (KR); Jae Yong Ryu, Gumi-si (KR)

(21) Appl. No.: 12/959,800

(22) Filed: Dec. 3, 2010

(30) Foreign Application Priority Data
Dec. 3, 2009 (KR) 10-2009-0119188
Jun. 30, 2010 (KR) 10-2010-0063183

(51) Int. Cl. H04R 1/02; H05K 7/00

(52) U.S. Cl. 381/333; 361/679.01

(57) ABSTRACT

Disclosed is a LCD device having a slim and simplified configuration. The disclosed LCD device includes: a liquid crystal display module; an upper cover configured to cover edges of the liquid crystal display module and to function as an upper system case and a top case; a lower cover configured to accommodate a backlight unit of the liquid crystal display module and to function as a lower system case and a bottom cover; a driver connector configured to protrude from one side surfaces of the upper and lower covers; a stand holder, with an accommodation groove which is formed to receive the driver connector, configured to support the liquid crystal display module; and a base deck combined with the stand holder and configured to include a system driver.

### CROSS-REFERENCE TO RELATED APPLICATION

This application claims priority under 35 U.S.C. 119 to Korean Patent Application Nos. 10-2009-119188 and 10-2010-063183, filed on Dec. 3, 2009 and Jun. 30, 2010, respectively which are hereby incorporated by reference in their entirety.

### BACKGROUND

1. Field of the Disclosure

This disclosure relates to a liquid crystal display (LCD) device, and more particularly to an LCD device that is easier to slim and simplify the configuration.

2. Description of the Related Art

Cathode ray tubes (CRTs) correspond to one of display devices which are widely used. The CRTs are mainly used as monitors for TVs, measuring apparatuses, information terminals, and so on. However, the heavy weight and large size of the CRTs have been a major hindrance to the manufacturing of small, light electronic products.

In other words, the CRTs have the limitations of weight and size in the current trend of small, light electronic products. Under such circumstances, LCD devices using an electro-optical effect, plasma display panels (PDPs) using a gas discharge, electro luminescence display devices using a electro-luminescent effect, and so on are expected to substitute for the CRTs.

Among the substitutable display devices, LCD devices are being actively researched. Also, LCD devices are gradually being used in a wide range of applications due to their advantages such as lightness, thinness, and low power consumption. Moreover, LCD devices are being manufactured to have even larger screens, be thinner, and consume less power, in order to meet the requirements of users. Such LCD devices display images by controlling the amount of light transmitted through liquid crystal.

LCD devices display images by controlling the amount of light transmitted through liquid crystal. However, LCD devices are not self-illuminating display devices, unlike CRTs. As such, an LCD device includes a backlight unit configured to have a separate light source, which provides light necessary to display an image, and disposed on the rear surface of an LCD panel. The backlight unit is classified as either an edge type or a direct type in accordance with the disposition of its light source.

The edge type backlight unit is mainly applied to comparatively small-sized LCD devices such as the monitors of lap-top and desk-top computers. The edge type backlight unit has good light uniformity, a lengthened lifespan, and the advantage of slimming the LCD device.

The direct type backlight unit has begun to be concentrically developed as the LCD device is enlarged to a size above 20 inches. The direct type backlight unit forces light to be directly irradiated onto the entire surface of the LCD panel. To this end, the direct type backlight unit includes a plurality of light sources arranged on the lower surface of a diffusion plate. Since the direct type backlight unit has a higher light efficiency than the edge type backlight unit, it is mainly used for LCD devices of a large size which require a high brightness.

In order to provide an ordinarily completed LCD device, the backlight unit is first assembled with the LCD panel in an LCD module. The LCD module is assembled with a system driver. Then, upper and lower system cases are combined with each other in such a manner as to encompass the upper and lower portions of the LCD module without a display area thereof. Afterward, a fulcrum rod used to uphold the LCD module is assembled with the upper and lower cases before being combined with a support base. In other words, the above assembling process provides the completed LCD device of a stand type.

In this manner, the ordinary LCD can be completed by combining the LCD module, system driver, and upper and lower cases. As such, the thickness of the ordinary LCD device must be increased. In other words, the ordinary LCD device has a structural problem that is difficult to solve. Therefore, it is difficult to implement slimness of the LCD device.

### BRIEF SUMMARY

Accordingly, the present embodiments are directed to an LCD device that substantially obviates one or more of problems due to the limitations and disadvantages of the related art.

An object of the present embodiments is to provide an LCD device that is easer to slim and simplify the configuration.

Additional features and advantages of the embodiments will be set forth in the description which follows, and in part will be apparent from the description, or may be learned by practice of the embodiments. The advantages of the embodiments will be realized and attained by the structure particularly pointed out in the written description and claims hereof as well as the appended drawings.

According to one general aspect of the present embodiment, an LCD device includes: a liquid crystal display module; an upper cover configured to cover edges of the liquid crystal display module and to function as an upper system case and a top case; a lower cover configured to accommodate a backlight unit of the liquid crystal display module and to function as a lower system case and a bottom cover; a driver connector configured to protrude from one side surfaces of the upper and lower covers; a stand holder, with an accommodation groove which is formed to receive the driver connector, configured to support the liquid crystal display module; and a base deck combined with the stand holder and configured to include a system driver.

An LCD device according to another aspect of the present embodiment includes: a liquid crystal display module; an upper cover configured to cover edges of the liquid crystal display module and to function as an upper system case and a top case; a lower cover configured to accommodate a backlight unit of the liquid crystal display module and to function as a lower system case and a bottom cover; a driver connector configured to protrude from one side surfaces of the upper and lower covers; a connection cable outwardly output from the liquid crystal display module; a stand configured to uphold the liquid crystal display module; and a base deck combined with the stand and configured to include a system driver which is connected with the connection cable inserted through the stand.

Other systems, methods, features and advantages will be, or will become, apparent to one with skill in the art upon examination of the following figures and detailed description. It is intended that all such additional systems, methods, features and advantages be included within this description, be within the scope of the invention, and be protected by the following claims. Nothing in this section should be taken as a limitation on those claims. Further aspects and advantages are discussed below in conjunction with the embodiments. It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the embodiments and are incorporated in and constitute a part of this application, illustrate embodiment(s) of the invention and together with the description serve to explain the disclosure. In the drawings:

FIG. 1 is a disassembled perspective view showing an LCD module;

FIG. 2 is a perspective view showing an LCD device according to an embodiment of the present disclosure;

FIG. 3 is a cross-sectional view showing the LCD device of FIG. 2;

FIG. 4 is a perspective view showing the rear side of an LCD device according to another embodiment of the present disclosure;

FIG. 5 is a disassembled perspective view showing the base deck and stand shown in FIG. 4; and

FIG. 6 is a disassembled perspective view showing the base deck shown in FIGS. 4 and 5.

### DETAILED DESCRIPTION

Reference will now be made in detail to the embodiments of the present disclosure, examples of which are illustrated in the accompanying drawings. These embodiments introduced hereinafter are provided as examples in order to convey their spirits to the ordinary skilled person in the art. Therefore, these embodiments might be embodied in a different shape, so are not limited to these embodiments described here. Also, the size and thickness of the device might be expressed to be exaggerated for the sake of convenience in the drawings. Wherever possible, the same reference numbers will be used throughout this disclosure including the drawings to refer to the same or like parts.

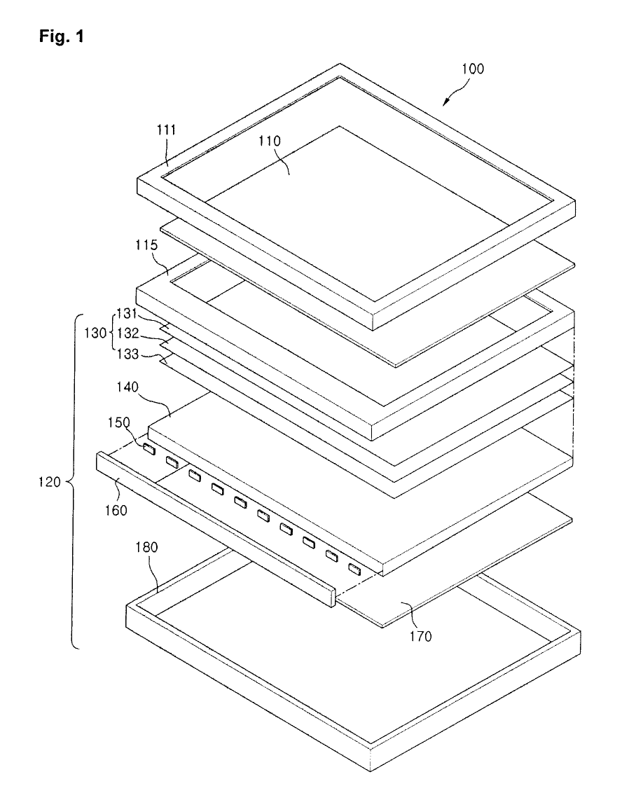

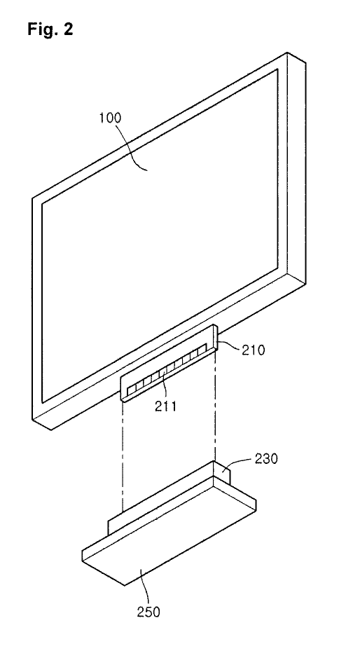

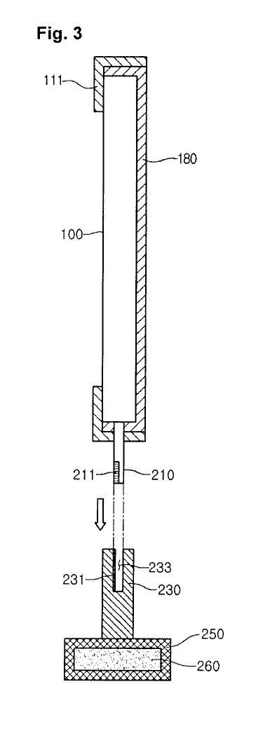

FIG. 1 is a disassembled perspective view showing an LCD module. FIG. 2 is a perspective view showing an LCD device according to an embodiment of the present disclosure. FIG. 3 is a cross-sectional view showing the LCD device of FIG. 2. As shown in FIGS. 1 through 3, an LCD device according to one embodiment of the present disclosure includes an LCD module 100, a stand holder 230 configured to uphold the LCD module 100, and a base deck 250 connected with the stand holder 230.

The LCD module 100 includes an LCD panel 110 configured to display images, and a support main 115 configured to support the rear surface edges of the LCD panel 110. The LCD module 100 further includes a backlight unit 120 disposed on the rear surface of the LCD panel 110 and configured to apply light to the LCD panel 110, and a upper cover 111 configured to encompass the edges of the LCD panel 110.

The LCD panel 110 includes a color filter substrate (not shown) and a thin film transistor substrate (not shown) disposed opposite each other and combined to maintain a uniform cell gap between them. The LCD panel 110 further includes a liquid crystal layer (not shown) interposed between the two substrates.

Although they are not shown in detail in the drawings, the color filter substrate and the thin film transistor substrate will now be described in detail. The thin film transistor substrate includes a plurality of gate lines and a plurality of data lines formed to cross each other, and thin film transistors formed at the intersections of the plurality of gate lines and the plurality of data lines. The plurality of gate lines and the plurality of data lines crossing each other define the pixels. The thin film transistors are connected to pixel electrodes each included in the pixels, respectively. On the other hand, the color filter substrate includes: red, green, and blue color filters opposite to the pixels; a black matrix configured to rim each of the color filters; and a common electrode formed to cover the color filters and the black matrix. The black matrix is formed to shield the gate lines, the data lines, and the thin film transistors.

The backlight unit 120 disposed under the LCD panel 110 includes a box-shaped bottom cover 180 with an opened upper surface, a metal PCB 160 disposed at an inner side of the bottom cover 180, and a plurality of light emission diodes (LEDs) 150 loaded on the metal printed-circuit-board (PCB) 160. The backlight unit 120 further includes a light guide plate 140 disposed parallel to the plurality of LEDs 150 and configured to convert spotted incident lights into two-dimensional light, a reflection sheet 170 disposed under the light guide plate 140 and configured to reflect light progressing downwardly from the light guide plate 140 toward the LCD panel 110, and optical sheets 130 disposed over the light guide plate 140 and configured to scatter and converge incident light from the light guide plate 140.

The optical sheet 130 includes a diffusion sheet 133, a converging sheet 132, and a protective sheet 131. The diffusion sheet 133 is configured to scatter light. The converging sheet 132 is configured to converge the scattered light. The protective sheet 131 is used to protect a converging pattern formed on the converging sheet 132.

The LCD device still further includes an outwardly protruded driver connector 210 mounted to one side surfaces of the upper and lower covers 111 and 180 and connected to panel and backlight drivers of the LCD module 100. The driver connector 210 is formed to include a material of great strength and to penetrate through one side surfaces of the upper and lower covers 111 and 180. The driver connector 210 includes a connection pad 210 formed on one surface of its outwardly protruded end.

The stand holder 230 used to uphold the LCD module 100 is formed to include an accommodation groove 233. The accommodation groove 233 is formed to progress from the upper surface toward the inner side of the stand holder 230. Such an accommodation groove 233 receives the driver connector 210 which is protruded from one side surfaces of the upper and lower covers 111 and 180.

The stand holder 230 is further configured to include a stand pad 231 formed to face the connection pad 211 which is formed on one surface of the end of the driver connector 210. The stand pad 231 is formed on one inner side surface of the accommodation groove 233.

The base deck 250 combined with the stand holder 230 is configured to include a system driver 260 within it. The system driver 260 within the base deck 250 is electrically connected to the driver connector 210 through the stand holder 230. In view of this point, the stand holder 230 further functions to connect the driver connector 210 to the system driver 260. To this end, the stand holder 230 still further includes wirings (not shown) formed to electrically connect the system driver 260 with the stand pad 231 which is formed on the inner side surface of the accommodation groove 233.

On the other hand, although it is not shown in detail in the drawings, the system driver 260 includes the panel driver, the backlight driver, and a power voltage supplier. The panel driver is used to drive the LCD panel 110. The backlight driver is used to driver the backlight unit 120. The power voltage supplier functions to provide a variety of power voltage necessary to drive the LCD module 100. The configuration of the system driver 260 will be explained in detail in the description of FIG. 6.

As described above, the LCD device according to one embodiment of the present disclosure includes an upper cover 111 configured to function as upper system case and top case, and a lower cover 180 configured to function as lower system case and bottom cover. Also, the LCD device forces the system driver 260 to be disposed in the inner side of the base deck 250. As such, the LCD device has an advantage of being easy to make slim. The LCD device being easy to make slim can reduce all the packing and transferring costs. Therefore, the price of the LCD device can become lower.

Moreover, the LCD device according to one embodiment of the present disclosure allows the LCD module 100, the stand holder 230 and the base deck 250 to be separately packed and transferred. As such, the LCD module 100, the stand holder 230 and the base deck 250, which are included in the LCD device, can be independently sold. The distribution cost of the LCD device can be cut down. Therefore, the price of the LCD device can be lowered.

Furthermore, the LCD device according to one embodiment of the present disclosure makes it possible to enable each of the driver connector 210, stand holder 230 and base deck 250 to be standardized in a fixed shape or model, regardless of the size of the LCD module 100.

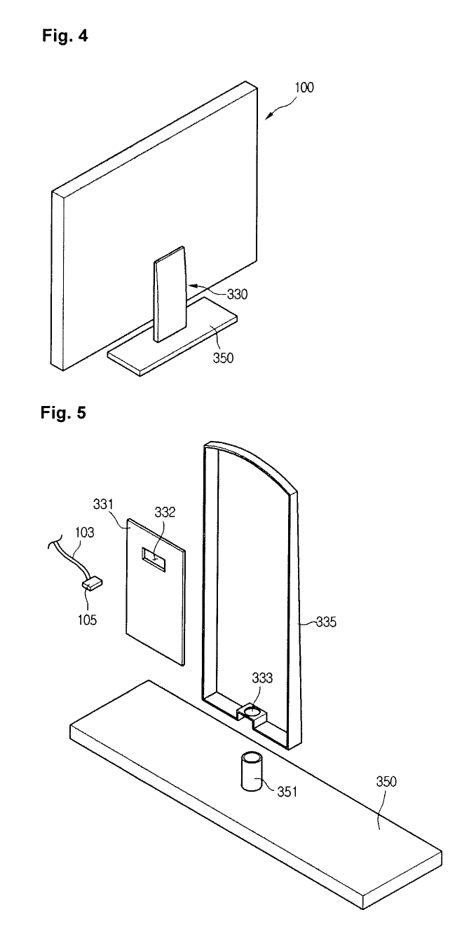

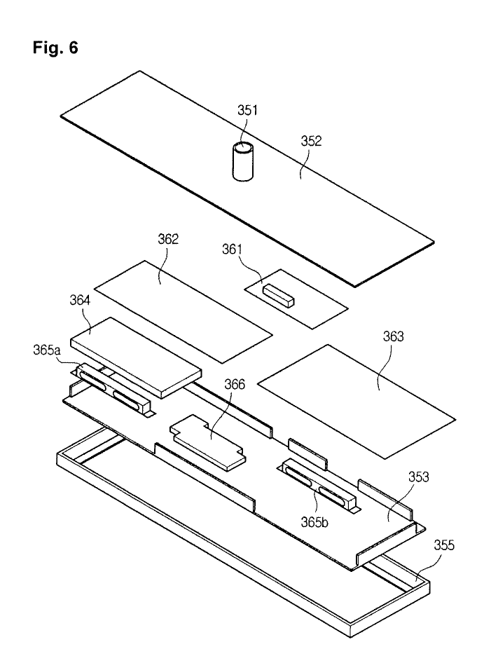

FIG. 4 is a perspective view showing the rear side of an LCD device according to another embodiment of the present disclosure. FIG. 5 is a disassembled perspective view showing the base deck and stand shown in FIG. 4. FIG. 6 is a disassembled perspective view showing the base deck shown in FIGS. 4 and 5.

As shown in FIGS. 4 through 6, the LCD device according to another embodiment of the present disclosure includes an LCD module 100. The LCD module 100 included in the LCD device of another embodiment is similarly configured with that of the LCD device of one embodiment. As such, with reference to the LCD module 100, the description of one embodiment to be repeated in another embodiment of the present disclosure will be omitted.

The LCD device according to another embodiment of the present disclosure further includes a source PCB (not shown) disposed in the inner side of the LCD module 100, and a connection cable 103 configured to connect the source PCB to a system driver (not shown) which is included in the inner side of a base deck 350. The connection cable 103 includes a cable connector 105 mounted at its end and combined with the system driver.

The LCD device according to another embodiment of the present disclosure still further includes a stand 330 configured to couple the LCD module 100 with the base deck 350. The stand 330 includes a stand bracket 331 combined with the rear surface of the LCD module 100, and a stand case 335 configured to encompass the stand bracket 331.

The stand bracket 331 is fastened to the rear surface of the LCD module 100 by means of screws. Alternatively, the stand bracket 331 is formed in a hook shape being easily fastened to the rear surface of the LCD module 100. Also, the stand bracket 331 is formed to include a first penetration hole 332 through which the connection cable 103 passes.

The stand case 335 includes a second penetration hole 333 formed in its lower surface. The second penetration hole 333 guides the connection cable 103 inserted through the first penetration hole 332 to reach the inner side of the base deck 350.

The base deck 350 includes a guide cylinder (or pipe) 351 configured to pass through the second penetration hole 333, and a top support cover 352 configured to support the stand 330 (i.e., the stand case 335). The base deck 350 further includes a bottom support cover 335 on which the system driver is disposed, and a side cover 353 configured to surround all edges of the bottom support cover 355.

The guide cylinder 351 is fastened to the central portion of the top support cover 352 and installed to penetrate through the top support cover 352. Such a guide cylinder 351 inserted through the second penetration hole 333 is used to rotatably hold the stand case 335. Also, the guide cylinder 351 guides the connection cable 103 inserted through the first penetration hole 332 to the inner side of the base deck 350.

The system driver disposed in the inner side of the base deck 350 includes a connector board 361 provided with a PCB connector, a main board 362 electrically connected to the connector board 361, and a power supply board 363 electrically connected to the connector board 361. The PCB connector is engaged with the cable connector 105 of the connection cable 103 which is inserted into the base deck 350 through the guide cylinder 351.

The power supply board 363 generates power voltages necessary to drive the main board 362 and applies the power voltages to the main board 362. Also, the power supply board 363 generates a variety of supply voltages necessary to drive the LCD module 100 and applies the supply voltages to the LCD module 100.

The main board 362 generates control and data signals necessary to drive the LCD panel. The control and data signals generated in the main board are applied to the LCD module 100 through the connection cable 103. The main board 362 further generates another control signal necessary to control the backlight unit. Another control signal for the backlight unit is applied from the main board 362 to the LCD module 100.

The base deck 350 still further includes a plurality of speaker modules 365a and 265b and a woofer module 364 which are configured to output sounds, and a touch module 366 configured to externally control the LCD device. The touch module 366 is used to control the turning-on/off of the LCD device, the brightness of display screen, the volumes of the speaker and woofer, and so on. To this end, the touch module 366 is controlled upon the manipulation of a user.

In this manner, the LCD device according to another embodiment of the present disclosure enables the LCD module 100 to include an upper cover configured to function as upper system case and top case, and a lower cover configured to function as lower system case and bottom cover. Also, the LCD device forces the system driver 260 including the main and power supply boards to be not only disposed in the inner side of the base deck 350 but also connected to the LCD module 100 through the connection cable 103. As such, the LCD device of another embodiment has an advantage of being easy to make slim. The LCD device of another embodiment being easy to make slim can reduce all the packing and transferring costs. Therefore, the price of the LCD device can become lower.

Moreover, the LCD device according to another embodiment of the present disclosure allows the LCD module 100 and the base deck 350 to be separately packed and transferred. As such, the LCD module 100 and the base deck 350, which are included in the LCD device, can be independently sold. The distribution cost of the LCD device can be cut down. Therefore, the price of the LCD device can be lowered.

Furthermore, the LCD device according to another embodiment of the present disclosure makes it possible to enable each of the stand 330 and base deck 350 to be standardized in a fixed shape or model, regardless of the size of the LCD module 100.

Although the present disclosure has been limitedly explained regarding only the embodiments described above, it should be understood by the ordinary skilled person in the art that the present disclosure is not limited to these embodiments, but rather that various changes or modifications thereof are possible without departing from the spirit of the present disclosure. Accordingly, the scope of the present disclosure shall be determined only by the appended claims and their equivalents.

What is claimed is:

1. A liquid crystal display device comprising:
a liquid crystal display module;
an upper cover configured to cover edges of the liquid crystal display module and to function as an upper system case and a top case;
a lower cover configured to accommodate a backlight unit of the liquid crystal display module and to function as a lower system case and a bottom cover;
a driver connector configured to protrude from one side surfaces of the upper and lower covers;
a stand holder, with an accommodation groove which is formed to receive the driver connector, configured to support the liquid crystal display module; and
a base deck combined with the stand holder and configured to include a system driver.

2. The liquid crystal display device claimed as claim 1, wherein the driver connector is used to electrically connect panel and backlight drivers of the liquid crystal display module to the system driver.

3. The liquid crystal display device claimed as claim 1, wherein the driver connector includes a connection pad formed on a surface of its end.

4. The liquid crystal display device claimed as claim 1, wherein the driver connector is connected to panel and backlight drivers within the liquid crystal display module through one side surfaces of the upper and lower covers.

5. The liquid crystal display device claimed as claim 3, further comprising a stand pad formed on a side surface of the accommodation groove which faces the connection pad.

6. The liquid crystal display device claimed as claim 5, wherein the stand holder includes wirings configured to electrically connect the stand pad with the system driver.

7. A liquid crystal display device comprising:
a liquid crystal display module;
an upper cover configured to cover edges of the liquid crystal display module and to function as an upper system case and a top case;
a lower cover configured to accommodate a backlight unit of the liquid crystal display module and to function as a lower system case and a bottom cover;
a driver connector configured to protrude from one side surfaces of the upper and lower covers;
a connection cable outwardly output from the liquid crystal display module;
a stand configured to uphold the liquid crystal display module; and
a base deck combined with the stand and configured to include a system driver which is connected with the connection cable inserted through the stand.

8. The liquid crystal display device claimed as claim 7, wherein the system driver includes:
a connector board directly connected to the connection cable;
a main board electrically connected to the connector board and configured to apply control signals necessary to driver a liquid crystal display panel and the backlight unit which are included in the liquid crystal display module; and
a power supply board electrically connected to the connector board and configured to generate voltages for the main board and the liquid crystal display module and to apply the voltages to the main board and the liquid crystal display module.

9. The liquid crystal display device claimed as claim 7, wherein the stand includes;
a stand bracket combined with the rear surface of the liquid crystal display module; and
a stand case configured to surround edges of the stand bracket.

10. The liquid crystal display device claimed as claim 9, wherein the stand bracket is formed to include a penetration hole through which the connection cable pierces.

11. The liquid crystal display device claimed as claim 9, wherein the stand case is formed to include a penetration hole which is formed in the lower surface of the stand case combined with the base deck and pierced by the connection cable.

12. The liquid crystal display device claimed as claim 7, wherein the base deck includes;
a top support cover;
a guide cylinder disposed at a central portion of the top support cover and configured to guide the connection cable into the base deck;
a bottom support cover on which the system driver is disposed; and
a side cover configured to surround edges of the bottom support cover.

13. The liquid crystal display device claimed as claim 7, wherein the base deck includes a plurality of speaker modules, a woofer module, and a touch module.
